(19) United States
(12) Patent Application Publication
(10) Pub. No.: US 2017/0057367 A1
(43) Pub. Date: Mar. 2, 2017

(54) Solar Windows for Electric Automobiles

(71) Applicant: Faraday&Future Inc., Gardena, CA (US)

(72) Inventors: Anil Paryani, Cerritos, CA (US); Phillip John Weicker, Pasadena, CA (US); Michael Hong, Irvine, CA (US); Garrett David Heinen, San Luis Obispo, CA (US)

(73) Assignee: Faraday&Future Inc., Gardena, CA (US)

(21) Appl. No.: 15/245,959

(22) Filed: Aug. 24, 2016

Related U.S. Application Data
(60) Provisional application No. 62/212,736, filed on Sep. 1, 2015.

(51) Int. Cl. B60L 11/18; B60J 1/00; H02S 40/30; H02S 40/38; H02M 3/335; H01L 31/0468

(52) U.S. Cl. CPC B60L 11/1811; H02M 3/33546; H01L 31/0468; H02S 40/30; H02S 40/38; B60J 1/00

(57) ABSTRACT

A photovoltaic power source for an electric automobile includes at least one window including a transparent photovoltaic cell; a DC-DC converter in electrical communication with the at least one window transparent photovoltaic cell; and a battery in electrical communications with the DC-DC converter.

### CROSS REFERENCE TO RELATED APPLICATION

This application claims the benefit of priority based on U.S. Provisional Patent Application No. 62/212,736 filed on Sep. 1, 2015, the entire disclosure of which is incorporated by reference.

### TECHNICAL FIELD

The present disclosure relates generally to photovoltaic cell power systems and, more specifically, to photovoltaic cell power systems incorporated into automobile windows.

Total electric automobiles are distance-limited both by the amount of charge the automobile can hold in its batteries beforeit needs to recharge and how fast the automobile draws on that charge. The amount of storage is limited by the size and capacity of the batteries. Larger capacity batteries carry more charge, but typically increase the weight of the automobile and this in turn requires the automobile motors to use more energy to move the automobile because of the extra mass. Therefore, rather than increasing the battery capacity, continuous charging of the batteries using photovoltaic cells has been considered to supplement the range of the electric automobile and to help avoid over-discharging the batteries.

Experimental models of long distance, solar powered electric automobiles are generally single person vehicles having substantially the automobile's entire available surface covered with solar cells. In order to travel the furthest distance on a single charge, most experimental long distance, solar powered automobiles are designed for a single passenger to conserve weight and have an extreme aerodynamic profile configured to reduce drag on the automobile as it moves. These automobiles, although interesting technologically, would not be acceptable for everyday use.

Present day electric automobiles charge batteries at charging stations that draw power from the electric grid. Because recharging the batteries takes a non-negligible amount of time, whatever can be done to conserve the charge in the battery should be considered.

The disclosed solar windows for electric automobiles are directed to mitigating or overcoming one or more of the problems set forth above and/or other problems in the prior art.

### SUMMARY

One aspect of the present disclosure is directed to a photovoltaic power source for an electric automobile. The power source may include at least one window including a transparent photovoltaic cell; a DC-DC converter in electrical communication with the at least one window transparent photovoltaic cell; and a battery, in electrical communications with the DC-DC converter.

Another aspect of the present disclosure is directed to an electric automobile. The electric automobile may include: a body; at least one window in the body, the at least one window comprising a transparent photovoltaic cell; a DC-DC converter, mounted in the body and in electrical communication with the at least one window transparent photovoltaic cell; and a battery, mounted in the body and in electrical communication with the DC-DC converter.

Yet another aspect of the present disclosure is directed to a method for charging a battery in an electric automobile. The method may include steps of: generating power from a transparent photovoltaic cell included in at least one window of the electric automobile; controlling the generated power with a DC-DC converter in electrical communication with the at least one window transparent photovoltaic cell; and charging a battery mounted in the vehicle and in electrical communication with the DC-DC converter.

### BRIEF DESCRIPTION OF THE DRAWING

The structure and function of the disclosed embodiments can be best understood from the description herein in conjunction with the accompanying figures. The figures are not necessarily to scale, emphasis instead generally being placed upon illustrative principles. The figures are to be considered illustrative in all aspects and are not intended to limit the disclosed embodiments, the scope of which is defined only by the claims.

FIG. 1 is a perspective diagram of an embodiment of an electric automobile with photovoltaic transparent windows as the sunroof and rear windows;

FIG. 2 is a schematic diagram of an embodiment of a DC-DC converter for use with the photovoltaic transparent windows of FIG. 1; and

FIG. 3 is a table showing the states of the transistors and diodes in the embodiment of the converter shown in FIG. 2.

### DETAILED DESCRIPTION

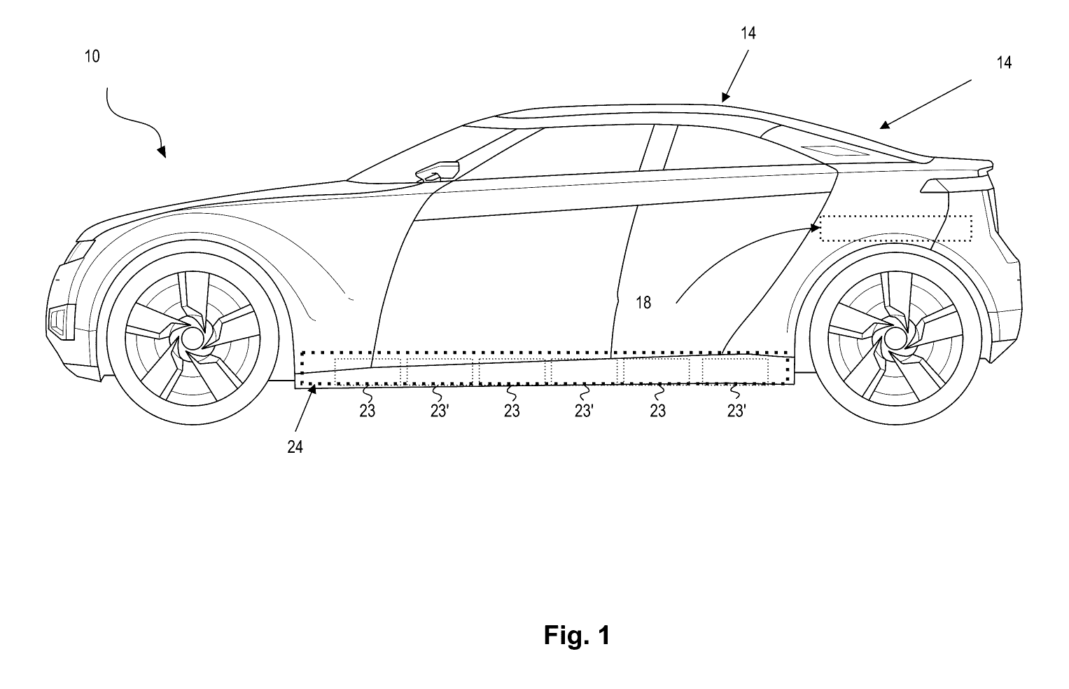

Referring to FIG. 1, an embodiment of an electric automobile 10 includes transparent photovoltaic cells (throughout this application the term “photovoltaic cells” is used interchangeably with the term “solar cells”) connected together to form one or more photovoltaic or solar panels 14, voltage-conditioning electronics 18 (also referred to as a “DC-DC power converter 18”) and a plurality of battery strings 23, 23′ (generally 23) (also referred to as “battery pack strings”) that make up a vehicle battery 24 mounted within the body of the automobile 10.

The solar panels 14 replacing the sunroof window and rear window of the automobile will generate a maximum of about 200 watts of power at 50 volts. The sunroof and rear window were chosen because of their position in the automobile. These windows are exposed to significant sunlight and yet the reduction in light passing through the panels will not affect the safety of the vehicle as would be the case, for example, in placing the transparent solar panels in the position of the windshield. However, depending on the level of transparency, transparent photovoltaics may be used for all windows. It is noted that as the transparency of photovoltaic cells increases, the amount of power generated decreases. For example with a transparency of 10% the power produced is about 47 W/m². As the transparency increases to 30%, the power generated decreases to 35 W/m².

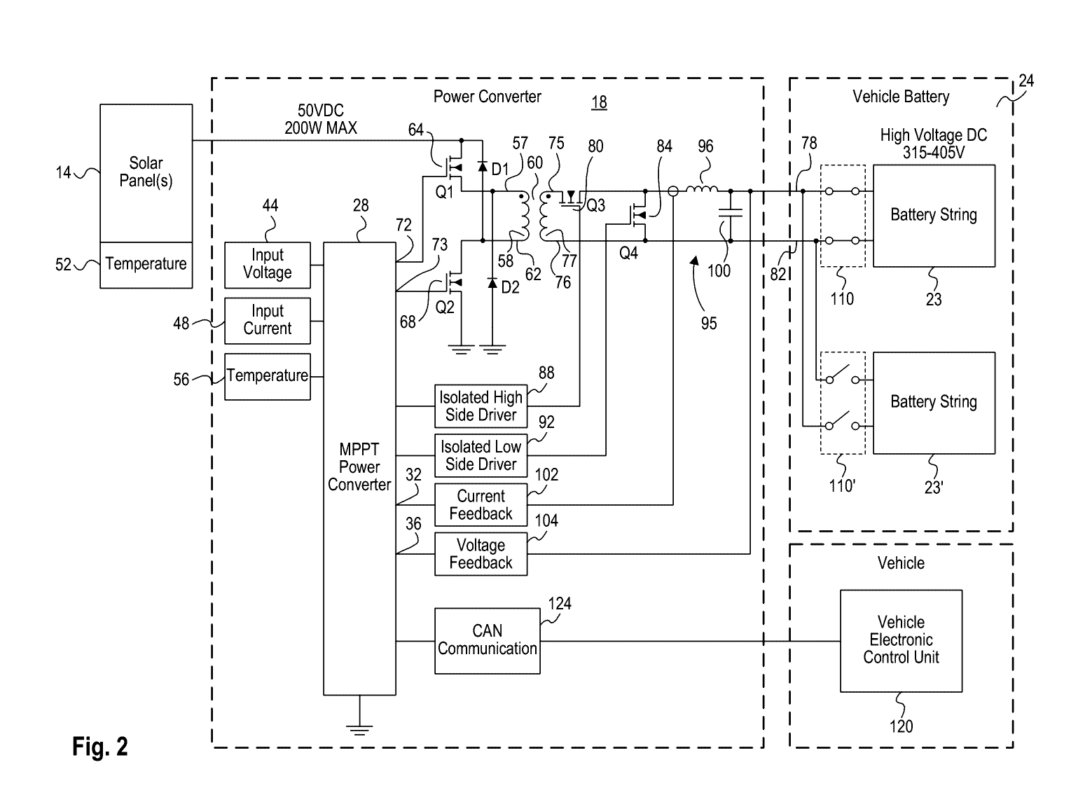

Referring to FIG. 2, the photovoltaic cells of the solar panels 14 are connected to the battery 24 through the DC-DC power converter 18. In one embodiment, converter 18 is provided as a Maximum Power Point Tracker (MPPT) DC-DC converter and power from the solar panels 14 at 50 VDC and 200 W maximum power is passed through the MPPT DC-DC converter. The MPPT DC-DC converter utilizes a MPPT Power Converter controller 28 to control the power being supplied to the battery 24. In effect, the MPPT 28 matches the power supplied by the photovoltaic cells of the solar panels 14 to the requirements of the battery 24 to reduce power loss. The DC-DC power converter is mounted within the body of the automobile 10.

The MPPT Power Converter controller 28 is programmed to monitor a current 32 and a voltage 36 supplied to the battery strings 23, 23′, an input voltage 44, and an input current 48 from the solar panels 14. Because the power output by the solar panels 14 varies with temperature, the solar panels 14 include a temperature sensor 52. The panel temperature sensor 52 provides an input signal to a temperature input 56 of the MPPT Power Converter controller 28.

Power from the solar panels 14 is input to a first side 57 of a primary coil 58 of a transformer 60 through a FET Q1 64. A second FET Q2 68 is connected between a second side 62 of the primary coil 58 and ground. A diode D1 is connected between the second side 62 of the primary coil 58 and the output of the photovoltaic panels 14. A second diode D2 is connected between first side 57 of the primary coil 58 and ground.

A first side 75 of a secondary coil 76 of the transformer 60 is connected to a first side 78 of battery 24 through a FET Q3 80. A second side 77 of the secondary coil 76 of transformer 60 is connected to the second side 82 of the battery 24. A FET Q4 84 is connected between the first and second sides 75, 77 of the secondary coil 76. A filter 95 constructed from an inductor 96 and a capacitor 100 is positioned between the FET Q4 84 and the battery 24. The inductor 96 is connected between FET Q3 80 and the first side 78 of the battery 24, and the capacitor is connected between the first side 78 and second side 82 of the battery 24.

The gate of FET Q1 64 is controlled by an output port 72, and the gate of FET Q2 68 is controlled by an output port 73 of the MPPT Power Converter controller 28. Similarly, the gate of FET Q3 80 and the gate of FET Q4 84 are controlled by an isolated high side driver 88 and an isolated low side driver 92, respectively, under control of two output ports of the MPPT Power Converter controller 28. An isolated current feedback monitor 102, in one embodiment a Hall effect current sensor, and an isolated voltage feedback monitor 104 provide information about the current and voltage provided to the battery 24 to the input ports 32 and 36, respectively, of the MPPT Power Converter controller 28.

Each of the battery strings 23, 23′ is connected to the first and second sides of the battery 24 through respective individual switches 110, 110′. The switches 110, 110′ are controlled by an external vehicle electronic control unit (ECU) 120.

The MPPT Power Converter controller 28 communicates with the vehicle Electronic Control Unit 120 through a CAN (Controller Area Network) bus interface 124 to exchange data such as maximum voltage, maximum charge current, temperature, system status, system faults and estimated available power, among others.

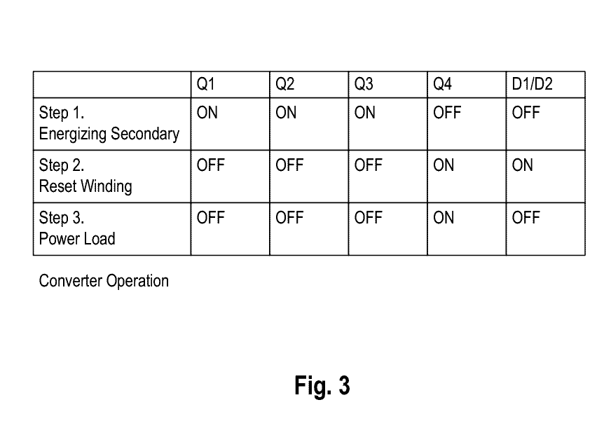

Referring to FIG. 3, in operation, the MPPT Converter controller 28 first turns on FET Q1 64, FET Q2 68, and FET Q3 80 and turns off FET Q4 84. In this state, diodes D1 and D2 are reverse-biased, and are off. This allows current to flow through the primary coil 58 of the transformer 60 and induce a current in the secondary coil 76. This current is allowed to pass through FET Q3 80 to the filter 95.

The MPPT Power Converter controller 28 next turns off FET Q1 64, FET Q2 68, and FET Q3 80 and turns on FET Q4 84. This stops the current from flowing through the primary coil 58, collapsing the field of the transformer 60 and reducing the current in the secondary coil 76 to zero. The turning on and off FET Q1 64 effectively changes the DC voltage from the photovoltaic panel into square wave DC, causing an oscillating magnetic field to be generated by the primary coil 58.

The MPPT Power Converter controller also turns on FET Q4 84, allowing the secondary winding to redistribute charge and reset. In this state, diodes D1 and D2 are forward-biased and are on. Once the transformer 60 is reset, the diodes D1 and D2 are again reverse-biased and are off, and only FET Q4 84 is on to permit current from FET Q1 64 to flow to the battery 24.

The MPPT Power Converter controller 28 controls other functions of the charging system. For example, if the temperature of the photovoltaic cell array 14 exceeds a certain value, the MPPT Power Converter controller monitors the temperature, current, and voltage of the solar panels 14 so that it may take proper action depending upon the values of the parameters. If any of the values are out of range, the converter will shut off. The converter uses the monitored input values to estimate the available output power and to maintain maximum power output from the converter despite changing incident light and without collapsing the photovoltaic cell voltage, so as to maintain the highest efficiency.

In another embodiment, the vehicle turns off or reduces power to any non-essential vehicle electronics to reduce current draw, which leads to a more effective transfer of energy from sunlight to the battery.

Unless otherwise indicated, all numbers expressing lengths, widths, depths, or other dimensions, and so forth used in the specification and claims are to be understood in all instances as indicating both the exact values as shown and as being modified by the term “about,” Accordingly, unless indicated to the contrary, the numerical parameters set forth in the specification and appended claims are approximations that nay vary depending upon the desired properties sought to be obtained. At the very least, and not as an attempt, to limit the application of the doctrine of equivalents to the scope of the claims, each numerical parameter should at least be construed in light of the number of reported significant digits and by applying ordinary rounding techniques. Any specific value may vary by 20%.

The terms “a,” “an,” “the,” and similar referents used in the context of describing the disclosed embodiments (especially in the context of the following claims) are to be construed to cover both the singular and the plural, unless otherwise indicated herein or clearly contradicted by context. All methods described herein can be performed in any suitable order unless otherwise indicated herein or otherwise clearly contradicted by context. The use of any and all examples, or exemplary language (e.g., “such as”) provided herein is intended merely to better illuminate the disclosure and does not pose a limitation on the scope of any claim. No language in the specification should be construed as indicating any non-claimed element essential to the practice of the disclosed embodiments.

Groupings of alternative elements or embodiments disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified, thus fulfilling the written description of all Markush groups used in the appended claims.

Certain embodiments are described herein, including the best mode known to the inventor for trying out the spirit of the present disclosure. Of course, variations on these described embodiments will become apparent to those of ordinary skill in the art upon reading the foregoing description. The inventor expects skilled artisans to employ such variations as appropriate, and the inventor intends for the disclosed embodiments to be practiced otherwise than specifically described herein. Accordingly, the claims include all modifications and equivalents of the subject matter recited in the claims as permitted by applicable law. Moreover, any combination of the above-described elements in all possible variations thereof is contemplated unless otherwise indicated herein or otherwise clearly contradicted by context.

It will be apparent to those skilled in the art that various modifications and variations can be made to the disclosed remote control system and related methods. Other embodiments will be apparent to those skilled in the art from consideration of the specification and practice of the disclosed remote control system and related methods. It is intended that the specification and examples be considered as exemplary only, with a true scope being indicated by the following claims and their equivalents.

What is claimed is:

1. A photovoltaic power source for an electric automobile, comprising:
at least one window comprising a transparent photovoltaic cell;
a DC-DC converter, in electrical communication with the at least one window transparent photovoltaic cell; and
a battery, in electrical communication with the DC-DC converter.

2. The photovoltaic power source of claim 1, wherein the DC-DC converter comprises:
a MPPT Converter Power controller; and
a FET in electrical communication with the transparent photovoltaic cell and in electrical communication with a primary of a transformer,
wherein the FET includes a gate in electrical communication with and controlled by the MPPT Converter Power controller.

3. The photovoltaic power source of claim 2 wherein the DC-DC converter further comprises:
a filter having an output and having an input in electrical communication with a secondary of the transformer; and
the output of the filter being in electrical communication with the battery.

4. The photovoltaic power source of claim 2 wherein the DC-DC converter further comprises:
a first diode connected between the primary of the transformer and the output of the transparent photovoltaic cell; and
a second diode connected between the primary of the transformer and ground.

5. The photovoltaic power source of claim 1 wherein electrical communication between the DC-DC converter and battery is controlled by an external electronic control unit.

6. An electric automobile, comprising:
a body;
at least one window in the body, the at least one window comprising a transparent photovoltaic cell;
a DC-DC converter, mounted in the body and in electrical communication with the at least one window transparent photovoltaic cell; and
a battery, mounted in the body and in electrical communication with the DC-DC converter.

7. The electric automobile of claim 6, wherein the DC-DC converter comprises:
a MPPT Converter Power controller; and
a FET in electrical communication with the transparent photovoltaic cell and in electrical communication with a primary of a transformer,
wherein the FET includes a gate in electrical communication with and controlled by the MPPT Converter Power controller.

8. The electric automobile of claim 7 wherein the DC-DC converter further comprises:
a filter having an output and having an input in electrical communication with a secondary of the transformer; and
the output of the filter being in electrical communication with the battery.

9. The electric automobile of claim 7 wherein the DC-DC converter further comprises;
a first diode connected between the primary of the transformer and the output of the transparent photovoltaic cell; and
a second diode connected between the primary of the transformer and ground.

10. The electric automobile of claim 7 wherein electrical communication between the DC-DC converter and battery is controlled by an external electronic control unit.

11. A method for charging a battery in an electric automobile, comprising steps of:
generating power from a transparent photovoltaic cell included in at least one window of the electric automobile;
controlling the generated power with a DC-DC converter in electrical communication with the at least one window transparent photovoltaic cell; and
charging a battery mounted in the vehicle and in electrical communication with the DC-DC converter.

12. The method of claim 11, wherein the DC-DC converter include:
a MPPT Converter Power controller; and
a FET in electrical communication with the transparent photovoltaic cell and in electrical communication with a primary of a transformer;
the method further comprising controlling, by the MPPT Converter Power controller, a gate of the FET.

13. The method of claim 12, wherein the DC-DC converter further comprises:
a filter having an output and having an input in electrical communication with a secondary of the transformer; and
the output of the filter being in electrical communication with the battery.

14. The method of claim 12, wherein the DC-DC converter further comprises:
a first diode connected between the primary of the transformer and the output of the transparent photovoltaic cell; and
a second diode connected between the primary of the transformer and ground.

15. The method of claim 12, further including controlling electrical communication between the DC-DC converter and the battery by an external electronic control unit.
